(19) United States
(12) Patent Application Publication
(10) Pub. No.: US 2009/0293801 A1
(43) Pub. Date: Dec. 3, 2009

(54) PRODUCTION METHOD OF SILICON SINGLE CRYSTAL

(75) Inventor: Shunji KURAGAKI, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/473,478

(22) Filed: May 28, 2009

(30) Foreign Application Priority Data
Jun. 2, 2008 (JP) 2008-144564

(51) Int. Cl. C30B 15/30

(52) U.S. Cl. 117/32

(57) ABSTRACT

A method of growing a single crystal, wherein the yield in terms of specific resistance is improved by improving an effective segregation coefficient without affecting other characteristics, is provided: wherein a seed crystal provided to the lower end of a wire cable is immersed in melt in a crucible, a single crystal ingot is grown on the lower end portion of the seed crystal being elevated by pulling up the wire cable while rotating the same, and a horizontal magnetic field intensity to be applied to the silicon melt is changed in accordance with crystal positions along the growing axis direction of the single crystal ingot, so that an effective segregation coefficient of a dopant along the growing axis direction in the single crystal ingot becomes small.

### BACKGROUND OF THE INVENTION

1. Field of the Invention

The present invention relates to a production method of a silicon single crystal to be used for semiconductor devices.

2. Description of the Related Art

Silicon wafers used for semiconductor devices are mainly made from silicon single crystal grown by the Czochralski method (CZ method). The CZ method is to immerse a seed crystal in molten silicon in a quartz crucible and pull it up so as to grow a single crystal ingot below the seed crystal.

When producing a wafer from a single crystal ingot grown by the CZ method, specific resistance at each part of the single crystal ingot has to be taken into consideration. Generally, in a single crystal ingot produced as above, a segregation coefficient of a dopant to be added is smaller than 1 as shown in FIG. 1, therefore, the dopant concentration becomes higher and the specific resistance in the crystal becomes lower toward the end portion (tail part). In the single crystal ingot, a part where a specific resistance value is out of a predetermined range (specified range) cannot be used as a product. Generating of such a part decreases the number of wafers to be obtained from one single crystal ingot and the yield declines. Accordingly, to improve the yield, it is necessary to diminish the change rate (inclination) of specific resistance in the direction of a growing axis of the single crystal ingot and to increase the length of a part that exhibits a specific resistance value satisfying the spec.

In a single crystal ingot grown by the CZ method, however, due to segregation phenomena of a dopant to be added, it is inevitable that the specific resistance varies with an inclination to some degree along the growing axis direction. As a result, there has been proposed, for example, a method of making an impurity distribution partially flat along the growing direction by changing an effective segregation coefficient of a dopant along the growing direction by controlling the growing speed (speed of pulling up) and a rotation speed (refer to the Patent Article 1).

[Patent Article 1] The Japanese Unexamined Patent Publication No. H09-255479

However, in the method of controlling the pulling-up speed and rotation speed as explained above, changes of the pulling-up speed and rotation speed largely affect other wafer characteristics than specific resistance, that is, a point defect distribution on a plane, an oxygen concentration distribution and oxygen deposit density; and there arises a disadvantage that desired characteristics cannot be obtained stably. Therefore, it is substantially difficult to freely control the pulling-up speed and rotation speed to control the specific resistance, and a ratio of a part where the specific resistance fulfills a desired spec on a single crystal cannot be increased sufficiently, that is, the yield in terms of specific resistance cannot be improved sufficiently.

### SUMMARY OF THE INVENTION

An object of the present invention is to provide a method of growing a silicon single crystal, by which a yield in terms of specific resistance can be substantially improved by changing the effective segregation coefficient without affecting other characteristics than the specific resistance.

To attain the above object, the present inventors studied in various ways on the single crystal growing condition of applying a horizontal magnetic field. As a result, they found the fact that intensity of the magnetic field during growing the single crystal was dominant in changing an effective segregation coefficient but did not affect the point defect characteristics and oxygen characteristics much. Namely, they found that, when growing a single crystal, the effective segregation coefficient could be effectively changed by changing the magnetic field intensity.

According to the present invention, there is provided a method of growing a single crystal, for growing a single crystal ingot at a lower end portion of a seed crystal provided to a lower end of a wire cable by immersing the seed crystal in melt in a crucible and pulling up the wire cable while rotating the same; wherein a horizontal magnetic field intensity to be applied to the silicon melt is changed in accordance with crystal positions along the growing axis direction of the single crystal ingot, so that an effective segregation coefficient of a dopant along the growing axis direction in the single crystal ingot becomes small.

According to the present invention, it is possible to provide a method of growing a silicon single crystal, by which the yield in terms of specific resistance can be improved substantially by changing an effective segregation coefficient without affecting other characteristics than specific resistance.

### BRIEF DESCRIPTION OF DRAWINGS

These and other objects and features of the present invention will become clearer from the following description of the preferred embodiments given with reference to the attached drawings, in which:

FIG. 1 is a view showing a relationship between a position along the growing direction and specific resistance in the case where a single crystal was grown by the CZ method;

FIG. 2 is a view of the configuration of a single crystal growing device according to an embodiment of the present invention;

FIG. 3 is a view for explaining a growing method according to the embodiment that shows a relationship between an applied magnetic field intensity and an effective segregation coefficient;

FIG. 4A to FIG. 4C are views for explaining the growing method according to the present embodiment respectively show an effective segregation coefficient along the growing axis direction, magnetic field intensity and specific resistance; and

FIG. 5A and FIG. 5B are views for explaining the growing method according to the present embodiment respectively show a point defect arising area along the growing axis direction and an oxygen concentration distribution with those in an embodiment from the related art for comparison.

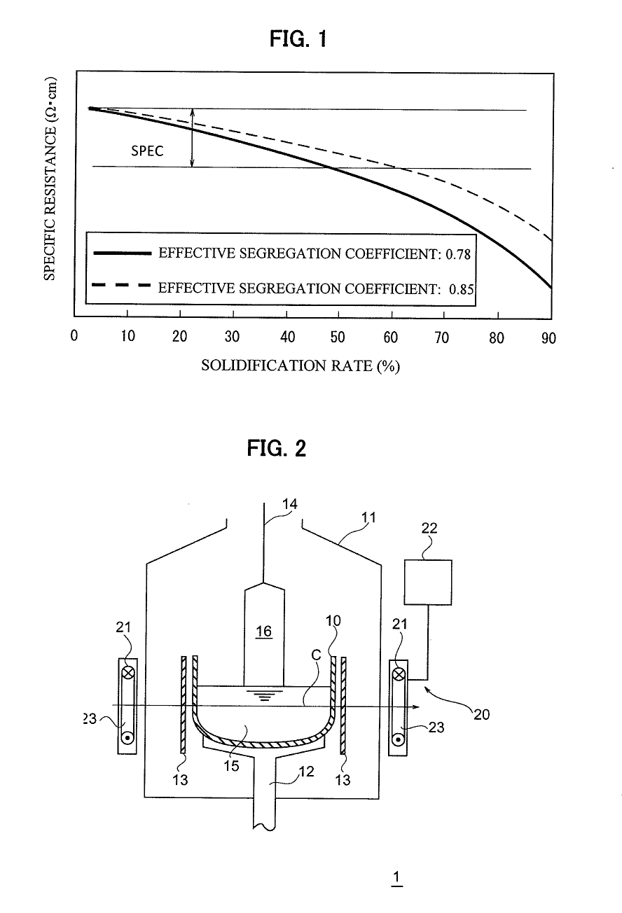

### DESCRIPTION OF THE PREFERRED EMBODIMENT

An embodiment of the present invention will be explained with reference to FIG. 2 to FIG. 5A and FIG. 5B.

First, an embodiment of a single crystal growing device according to the present invention will be explained with reference to FIG. 2.

FIG. 2 is a view showing the configuration of the single crystal growing device 1.

As shown in FIG. 2, the single crystal growing device 1 comprises a crucible 10, a chamber 11, a support axis 12, a heater 13, pull-up axis 14 and a magnetic field application device 20.

The crucible 10 is composed of an inner layer container made by quartz and an outer layer container made by graphite and held in the chamber 11 in a state of being supported by the support axis 12 in a freely rotatable and vertically movable way. The heater 13 is arranged around the crucible 10 along its outer circumference.

The pull-up axis 14, which can rotate and move up and down freely, is provided above the crucible 10. By attaching a seed crystal at the lower end portion of the pull-up axis 14, immersing the seed crystal in melt 15 in the crucible 10, and gradually pulling up the seed crystal from the melt 15 while rotating the pull-up axis 14 and the support axis 12 in the opposite directions from each other, a single crystal ingot 16 is formed below that.

Outside the chamber 11, a magnetic field application device 20 according to the present invention is provided for applying a horizontal-direction magnetic field to the melt 15 in the crucible 10. The magnetic field application device 20 comprises a pair of magnetic field application coils 21 arranged facing to each other with the crucible 10 positioned between them, a magnetic field intensity control unit 22 for controlling intensity of the magnetic field to be applied from the magnetic application coils 21, and drive units 23 for respectively supporting the magnetic application coils 21 and vertically moving the magnetic application coils 21 to a desired position.

The magnetic field intensity control unit 22 of the magnetic field application device 20 comprises a CPU, a RAM, a memory device and an input device, etc.; wherein data on magnetic field intensity with respect to progression of growing a single crystal ingot 16 is stored in advance in the memory device.

The magnetic field application device 20 refers to data on progression of growing input from a not shown control unit of the pull-up axis 14 and the above explained data on magnetic field intensity stored in the memory device in the magnetic field intensity control unit 22 and controls magnetic field intensity to be applied from the magnetic field application coils 21 to the melt 15 in accordance with the progression of growing a single crystal ingot 16. In other words, control is conducted by the magnetic field application device 20 in accordance with a position of growing (for example, a distance of the pull-up axis 14 from the lower end portion) of the single crystal ingot 16 along the growing axis direction.

The magnetic field application device 20 also controls positions of the magnetic field application coils 21 in the direction of a growing axis of the crystal by driving the drive units 23 in accordance with need, so that a magnetic force from the magnetic field application coils 21 effectively acts on the melt 15 and a crystal growing portion of the single crystal ingot 16. By the way, it can use another magnetic field application device applying a horizontal-direction magnetic field, for example, as a saddle-shaped magnetic field.

Next, an explanation will be made on the single crystal growing method according to the present invention by using the single crystal growing device 1 explained above.

First, data indicating a relationship between intensity of a magnetic field to be applied from the magnetic field application coils 21 to the melt 15 and a change of an effective segregation coefficient of a dopant is collected in advance. Specifically, for example, by growing a single crystal by arbitrarily changing the intensity of the magnetic field to be applied from the magnetic field application coils 21 to the melt 15 and measuring a dopant concentration at each position on the produced single crystal, an effective segregation coefficient corresponding to each magnetic field intensity can be detected. Data indicating detected correspondence between the magnetic field intensity and an effective segregation coefficient is stored in the memory device of the magnetic field intensity control unit 22.

In the data collecting, a single crystal ingot 16 may be grown by each of respective magnetic field intensities and a dopant concentration may be measured at the same position of the single crystal ingots 16, alternately, the magnetic field intensity may be gradually changed in a growing process of one single crystal ingot 16 and a dopant concentration at respective positions may be measured. Note that, in the latter case, changes of an effective segregation coefficient due to position difference along the growing axis direction have to be taken into consideration and a processing for correcting the change amount becomes necessary.

Note that, as a typical dopant to be added to silicon single crystal, boron, phosphor, antimony and arsenic, etc. may be mentioned. They all have a segregation coefficient of smaller than 1, but a change amount of the effective segregation coefficient due to a magnetic field application differs depending on a dopant to be used. Therefore, it is preferable to change the magnetic field intensity in accordance with dopant species to be used, and it is necessary to detect in advance values of effective segregation coefficients corresponding to respective magnetic field intensities as explained above for each dopant to be used.

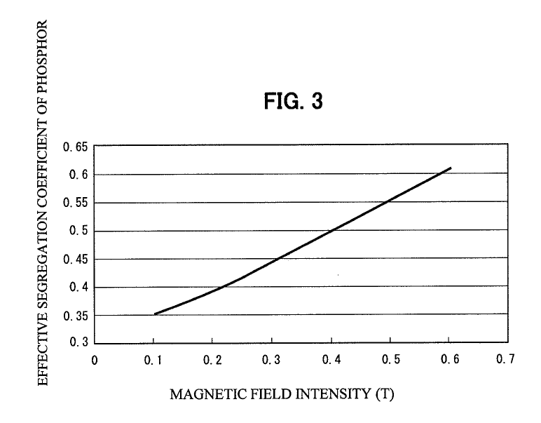

A data example indicating a relationship between the magnetic field intensities and effective segregation coefficients obtained as explained above is shown in FIG. 3. FIG. 3 is a graph showing a relationship between an effective segregation coefficient of phosphor as an impurity and a magnetic field intensity, wherein effective segregation coefficients when changing the magnetic field intensity from 1000 G to 6000 G are shown.

After collecting data as explained above, a single crystal ingot 16 is produced by the Czochralski method. Specifically, a seed crystal is attached to the lower end portion of the pull-up axis 14, the seed crystal is immersed in the melt 15 in the crucible 10, and the seed crystal is gradually pulled up from the melt 15 while rotating the pull-up axis 14 and the support axis 12 in the opposite directions from each other.

During the time, the melt 15 in the crucible 10 is applied with a magnetic field in the horizontal direction by the magnetic field application coils 21 of the magnetic field application device 20. Also, the intensity of the magnetic field to be applied at this time is controlled by the magnetic field intensity control unit 22 in accordance with a position of the single crystal ingot 16 along the crystal growing direction (the grow axis direction), so that the effective segregation coefficient becomes small at each position. Specifically, to obtain an amount of controlling the effective segregation coefficient at each position on the single crystal ingot 16 along the crystal growing direction, rates of changing the effective segregation coefficient along the growing axis direction are detected in advance in the case of growing a single crystal without applying a magnetic field and in the case of growing a single crystal by applying a certain magnetic field. Then, in accordance with the characteristics of changing of the effective segregation coefficient along the growing axis direction, a magnetic field is applied by changing the magnetic field intensity depending on the respective positions, so that a dopant concentration distribution becomes uniform along the single crystal ingot 16 along the growing axis direction.

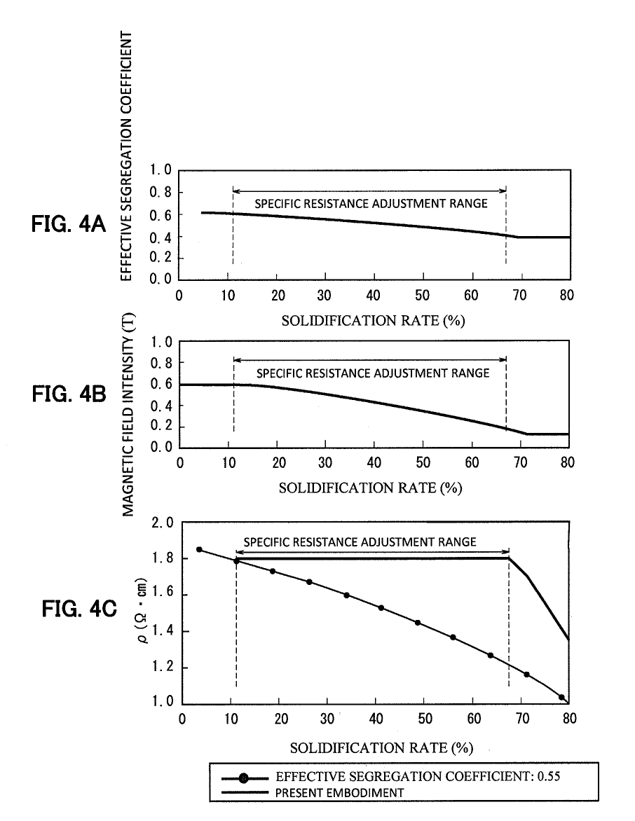

Specifically, for example, if a changing state of the effective segregation coefficient when growing a single crystal without applying a magnetic field has the characteristics as shown in FIG. 4A, with reference to the data detected in advance as explained above, a magnetic field is applied by changing the magnetic field intensity depending on the respective positions along the growing axis direction as shown in FIG. 4B.

As a result of growing a single crystal in the above explained method, an increase of the effective segregation coefficient along the growing axis direction in the single crystal ingot 16 due to a segregation coefficient of the dopant can be diminished. Consequently, as shown in FIG. 4C, a specific resistance of the grown single crystal ingot 16 is also maintained to be an almost same value over a long portion. Accordingly, a long portion having a specific resistance that satisfies a predetermined spec can be secured, and single crystal wafers can be efficiently produced from one single crystal ingot 16, that is, high-yield production can be attained.

Note that the graph plotted with black dots in FIG. 4C shows changes of the specific resistance along the growing axis direction when growing without applying a magnetic field and in a state where the effective segregation coefficient is 0.55, which is for a comparison with the case of growing in the method of the present embodiment.

As explained above, according to the method of growing a single crystal of the present embodiment, by applying a magnetic field in a horizontal direction to a melt 15 and changing the intensity of the magnetic field depending on the respective positions on the single crystal along the growing axis direction, so that the effective segregation coefficient becomes small at each position, that is, by controlling the magnetic field intensity to be gradually weaker in accordance with a growing amount of the single crystal; the specific resistance is controlled to be a value satisfying a desired spec on a sufficiently long portion along the growing axis direction of the grown single crystal ingot 16. Accordingly, a large number of wafers having desired characteristics of specific resistance can be produced by one single crystal growing device 1 and the yield in terms of specific resistance can be improved.

Furthermore, controlling of specific resistance, in other words, controlling of the effective segregation coefficient as above is attained by controlling the intensity of the magnetic field to be applied to the melt 15; so that an operation of widely changing the rotation speed of the pull-up axis 14 and the crucible 10 and changing of the pulling up speed of the pull-up axis 14, etc., which has been performed in the related art for unifying the dopant concentration, becomes unnecessary. Therefore, these controlling elements can be used for controlling a point defect distribution and an oxygen distribution in the same way as in the conventional ways.

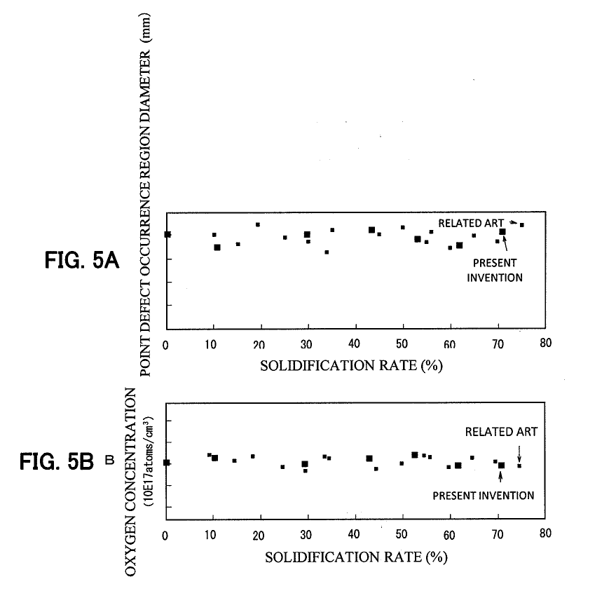

FIG. 5A and FIG. 5B show a point defect occurrence region distribution and an oxygen concentration distribution of single crystals grown by a method of not applying a magnetic field in the related art and by the method of applying a magnetic field while changing the intensity in the present embodiment, wherein the point defect occurrence region distribution and the oxygen concentration distribution are controlled by controlling the rotation speeds of the pull-up axis 14 and the crucible 10 and the pulling up speed of the pull-up axis 14. FIG. 5A shows the point defect occurrence region distribution and FIG. 5B shows the oxygen concentration distribution. Note that the point defect occurrence region distribution here means a Crystal Originated Particle (COP) occurrence region caused by vacancy clusters generated in a single crystal, and outer diameter positions of the generated COP occurrence regions are shown along the length direction (solidification rate) of the crystal. Also, in both of FIG. 5A and FIG. 5B, the small rectangular plotting is a detection result of a single crystal obtained by the growing method of the related art and the large rectangular plotting is a detection result of a single crystal obtained by the growing method of the present embodiment.

As shown in FIG. 5A and FIG. 5B, the results of the point defect occurrence region distribution and the oxygen concentration distribution are almost same in the method of the related art and the method of the present embodiment. Accordingly, it is known that, even if a magnetic field in the horizontal direction is applied to the melt 15 by the magnetic field application device 20 as in the present embodiment, being independent from this, these characteristics can be properly controlled by controlling in the same method as that in the related art.

It is also known that the method of applying a magnetic field in the horizontal direction in the present embodiment scarcely affects the point defect occurrence region distribution and the oxygen concentration distribution.

Note that the present embodiment is for easier understanding of the present invention and not to limit the present invention. Accordingly, respective elements disclosed in the above embodiments include all modifications in designs and equivalents belonging to the technical field of the present invention and can be freely, suitably modified in various ways.

### EXPLANATION OF REFERENCES

1 . . . single crystal growing device
   10 . . . crucible
   11 . . . chamber
   12 . . . support axis
   13 . . . heater
   14 . . . pull-up axis
   15 . . . melt
   16 . . . single crystal ingot
   20 . . . magnetic field application device
      21 . . . magnetic field application coil
      22 . . . magnetic field intensity control unit
      23 . . . drive

What is claimed is:

1. A method of growing a silicon single crystal, comprising
immersing the seed crystal in silicon melt in a crucible,
growing a single crystal ingot on a lower end portion of a seed crystal provided to a lower end of a wire cable,
pulling up the wire cable while rotating the same and,
applying a magnetic field to the silicon melt;
wherein an intensity of a horizontal magnetic field to be applied to the silicon melt is changed in accordance with crystal positions along the growing axis direction of the single crystal ingot, so that an effective segregation coefficient of a dopant along the growing axis direction in the single crystal ingot becomes small.

2. The method of growing a silicon single crystal as set forth in claim 1, wherein the magnetic field intensity is changed in accordance with dopant species to be used.

3. The method of growing a silicon single crystal as set forth in claim 1, wherein a rate of changing of an effective segregation coefficient of a dopant when changing the magnetic field intensity is obtained in advance for respective dopant species to be used, and the magnetic field intensity is changed to attain a uniform dopant concentration distribution along the growing axis direction in the single crystal ingot.
